(19) United States
(12) Patent Application Publication
(10) Pub. No.: US 2012/0043972 A1
(43) Pub. Date: Feb. 23, 2012

(54) METHOD AND CIRCUIT FOR REDUCING NOISE IN A CAPACITIVE SENSING DEVICE

(76) Inventor: Arun JAYARAMAN, San Ramon, CA (US)

(21) Appl. No.: 12/859,944

(22) Filed: Aug. 20, 2010

(51) Int. Cl. G01R 27/26

(52) U.S. Cl. 324/658

(57) ABSTRACT

A capacitive sensing circuit is provided. The capacitive sensing circuit includes a first capacitor and a charge-to-voltage converter circuit coupled to the first capacitor. The charge-to-voltage converter circuit includes a first current source that provides a first current to the first capacitor to charge the first capacitor and generate a time-varying voltage. The capacitive sensing circuit also includes a voltage-to-charge converter circuit coupled to the charge-to-voltage converter circuit, wherein the voltage-to-charge converter circuit samples the time-varying voltage and converts the time-varying voltage into a sampled charge at a predetermined sampling frequency. The capacitive sensing circuit further includes an integrator circuit coupled to the voltage-to-charge circuit, wherein the integrator circuit receives the sampled charge and integrates the sampled charge.

### BACKGROUND

1. Technical Field

The present disclosure is related to capacitive sensing devices and, in particular, a method and circuit for reducing noise in a capacitive sensing device.

2. Discussion of Related Art

Capacitive sensing devices are found in many of today's electronics. In particular, capacitive sensing devices are often found in handheld devices for enabling the touch screens of these devices. In these handheld devices, the capacitive sensing device detects the position on the screen of an operator's finger or other pointing device such as a stylus. The detected position is then interpreted by a processor to execute a program, move a cursor, or select an icon displayed on the touch screen. The capacitive sensing devices typically include a capacitive sensor, such as the sensor shown in FIGS. 1A, 1B, and 2.

FIG. 1A is a diagram illustrating a conventional two-terminal capacitive sensor 100. As shown in FIG. 1A, capacitive sensor includes a sense capacitor 102, which produces a voltage Vs₁ and Vs₂ at each plate of capacitor 102 proportional to a charge stored on capacitor 102. A first switch 104 is coupled in parallel to sense capacitor 102, and a second switch 106 is coupled to a top plate of sense capacitor 102 and a third switch 108 is coupled to a bottom plate of sense capacitor 102. When second switch 106 is closed, integrator circuit 110 is coupled to sense capacitor 102, and when third switch 108 is closed, sense capacitor 102 is coupled to ground. As shown in FIG. 1A, integrator circuit 110 includes an integration capacitor 112 coupled to an amplifier 114 in a negative feedback loop. A reference voltage V_{ref} is input into the positive terminal of amplifier 114. In operation, capacitive sensor 100 uses a series of charge and discharge pulses to transfer a quantum of charge into integration capacitor 112. After a predetermined interval of time, the quantum of charge stored in integration capacitor 112 is measured. The measurement of the charge stored in integration capacitor 112 is proportional to the charge stored in sense capacitor 102, and can be used to estimate the value of the charge stored in sense capacitor 102. Generally, the amount of charge Q stored on a capacitor is proportional to the voltage V across the terminals of the capacitor, such that Q=CV, C being the capacitance of the capacitor in farads.

In operation, capacitive sensor 100 is charged and discharged using a fixed clock frequency having a period of Tₛ. FIG. 1B is a timing diagram illustrating the charge and discharge timing of the sensor illustrated in FIG. 1A. As shown in FIG. 1B, during every period Tₛ, P₁ goes to a high state then a low state, and then P₂ goes to a high state and then a low state. When P₁ is at a high state, second switch 106 and third switch 108 are closed, and sense capacitor 102 is charged. When P₂ is at a high state, first switch 104 is closed, and sense capacitor 102 is discharged. This charge and discharge cycle allows for a charge to be built up on sense capacitor 102, and then discharged while a charge proportional to the charge stored on sense capacitor 102 to be sampled by integrator circuit 110 and measured. While the capacitive sensor 100 illustrated in FIGS. 1A and 1B can be used when both plates of sense capacitor 102 are forced to fixed voltages such as Vs₁ and Vs₂, many capacitive sensors have a plate that is coupled to ground.

FIG. 2 is a diagram illustrating a single terminal capacitive sensor 200 according to the prior art. As shown in FIG. 2, capacitive sensor 200 includes a sense capacitor 202 which has a top plate which is coupled to integrator circuit 204 via first switch 206, and bottom plate which is coupled to ground. Second switch 208, when closed and when first switch 206 is open, provides a path to ground for sense capacitor 202, allowing for the charge and discharge of sense capacitor 202 via the opening and closing of switches 206 and 208, similar to FIGS. 1A and 1B. Similar to integrator circuit 110, integrator circuit 204 includes an integration capacitor 210 coupled in a negative feedback loop with amplifier 212. However, as shown in FIG. 2, sense capacitor 202 having its back plate coupled to ground results in noise V_{N} which can affect the measurements by the integrator circuit 204, resulting in an inaccurate determination of the charge stored in sense capacitor 202.

Prior art attempts to minimize the noise appearing in the measured value have involved making successive measurements and integrating the charge on integration capacitor 210. Although this technique may improve the signal-to-noise ratio of the measurement with respect to certain frequencies of noise, it creates additional problems. For example, because the measurement involves repeated sampling of the charge, aliasing of the noise arises at the charge-discharge frequency, 1/Tₛ. This aliasing is indistinguishable from the capacitance of sense capacitor 202, making it very difficult to process out of the measured signal. Moreover, this aliasing becomes even more problematic in environments where there are many electrically driven sources operating together, each of which have periodic repetition frequency signals.

However, because the quantum of charge is not dependent on the duty-cycle of the charge-discharge pulse but only the charge-discharge frequency (Fₛ=1/Tₛ), other prior art attempts to minimize the noise appearing in the measured value have involved periodically changing the clock frequency, known as dithering the clock frequency or spread-spectrum clocking. Dithering the clock frequency or spread-spectrum clocking typically uses a clock having a frequency higher than charge-discharge frequency and passing the clock through a dual-modulus (N/N+1) frequency divider. The clock frequency randomly changes between Fₛ and (1+1/N)·Fₛ when the modulus is adjusted, which serves to mitigate some of the noise aliasing from multiples of the charge-discharge frequency Fₛ. However, this solution is also very imperfect because during measurement intervals when the charge-discharge frequency Fₛ is equal to the clock frequency, there is perfect aliasing of the noise at multiples of the charge-discharge frequency Fₛ to direct current DC which cannot be removed from the measurement. In order for this solution to substantially reduce noise sensitivity, a multi-modulus frequency divider needs to be used, which may increase the size of the sensing device and increase power dissipation due to a higher fundamental clock frequency required.

Therefore, there is a need to develop a capacitive sensing device that has improved noise characteristics using noise reduction techniques which do not alias the noise created by coupling a bottom plate of a sense capacitor to ground.

### SUMMARY

Consistent with embodiments of the present disclosure, a capacitive sensing circuit is provided. The capacitive sensing circuit includes a first capacitor and a charge-to-voltage converter circuit coupled to the first capacitor. The charge-to-voltage converter circuit includes a first current source that provides a first current to the first capacitor to charge the first capacitor and generate a time-varying voltage. The capacitive sensing circuit also includes a voltage-to-charge converter circuit coupled to the charge-to-voltage converter circuit, wherein the voltage-to-charge converter circuit samples the time-varying voltage and converts the time-varying voltage into a sampled charge at a predetermined sampling frequency. The capacitive sensing circuit further includes an integrator circuit coupled to the voltage-to-charge circuit, wherein the integrator circuit receives the sampled charge and integrates the sampled charge.

Consistent with some embodiments, there is also provided a method of generating a signal proportional to a charge of a capacitor, the generated signal having reduced noise. The method includes generating a time-varying voltage across a first capacitor by supplying a first current produced by a first current source to the capacitor, wherein a voltage build up on the first capacitor is periodically reset, sampling the time-varying voltage, generating a proportional charge that is proportional to a charge stored on the first capacitor based on the sampled time varying voltage, and accumulating the proportional charge on a second capacitor.

These and other embodiments will be described in further detail below with respect to the following figures.

### BRIEF DESCRIPTION OF THE DRAWINGS

FIG. 1A is a diagram illustrating a two-terminal capacitive sensor according to the prior art.

FIG. 1B is a timing diagram illustrating the charge and discharge timing of the sensor illustrated in FIG. 1A.

FIG. 2 is a diagram illustrating a single terminal capacitive sensor according to the prior art.

FIG. 3 is a diagram illustrating a capacitive sensor consistent with some embodiments.

FIG. 4 is a diagram illustrating a charge-to-voltage converter circuit consistent with some embodiments.

FIG. 5A is a diagram illustrating a voltage-to-charge converter circuit consistent with some embodiments.

FIG. 5B is a timing diagram illustrating the timing of the circuit illustrated in FIG. 5A.

FIG. 6 is a diagram illustrating a voltage-to-charge converter circuit consistent with some embodiments.

FIG. 7 is a timing diagram illustrating the timing of the circuit illustrated in FIG. 6.

FIG. 8 is a diagram illustrating a charge-to-voltage circuit consistent with some embodiments.

FIGS. 9A and 9B are diagrams illustrating a voltage-to-charge converter circuit consistent with some embodiments.

FIG. 10 is a timing diagram illustrating the timing of both processing stages of the circuits illustrated in FIGS. 9A and 9B.

FIG. 11 is a flowchart illustrating a method for generating a signal proportional to a charge of a capacitor having reduced noise consistent with some embodiments.

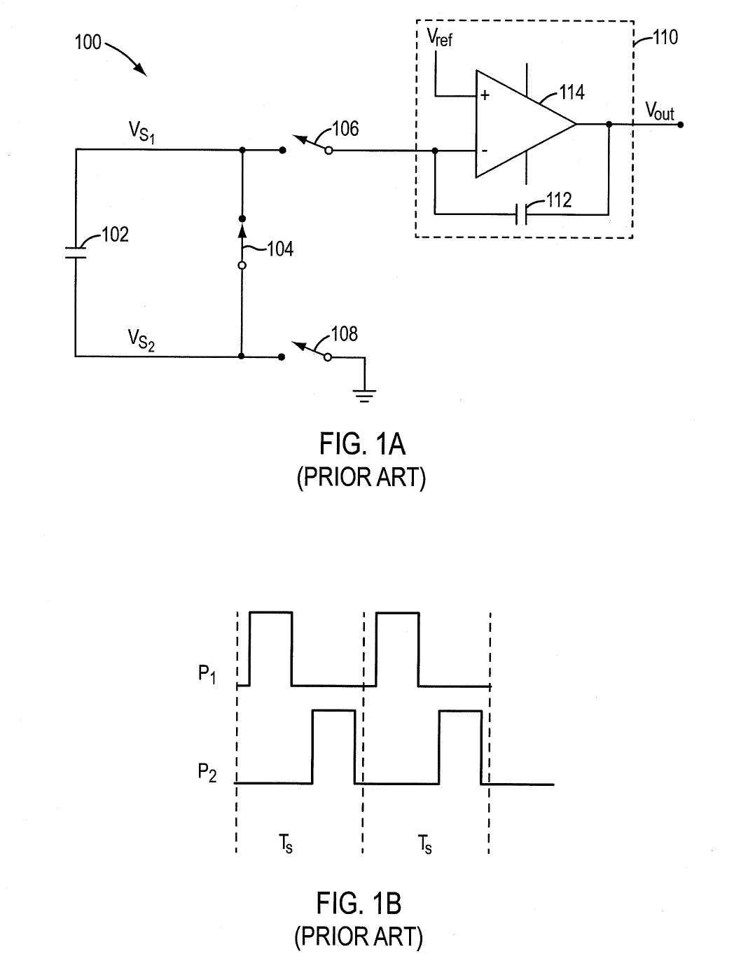

In the drawings, elements having the same designation have the same or similar functions.

### DETAILED DESCRIPTION

In the following description specific details are set forth describing certain embodiments. It will be apparent, however, to one skilled in the art that the disclosed embodiments may be practiced without some or all of these specific details. The specific embodiments presented are meant to be illustrative, but not limiting. One skilled in the art may realize other material that, although not specifically described herein, is within the scope and spirit of this disclosure.

Consistent with some embodiments, a capacitive sensor as described herein includes a two-stage architecture. The first stage may be a charge-to-voltage conversion circuit that includes an exciting source for charging a sense capacitor and generating a time-varying voltage. The second stage may be a voltage-to-charge conversion circuit that converts the generated time-varying voltage to a charge that is proportional to a charge on the sense capacitor. The sampled charge is then input into an integrator that provides a measurement of the charge stored on the sense capacitor from the proportional charge generated in the voltage-to-charge generating circuit.

Consistent with some embodiments, a fixed current source is used to charge the sense capacitor, and the voltage build up on the sense capacitor is periodically reset to zero by using at least one of a reset pulse or by changing the polarity of the fixed current source. In such embodiments, the voltage on the sense capacitor V_{c} is given by the following equation:

$${V}_{c} = \frac{1}{{C}_{s}} {\int }_{{T}_{0}}^{{T}_{1}} {I}_{Ref} d t + {\int }_{{T}_{0}}^{{T}_{1}} {V}_{n} ( t ) d t ,$$

where Cₛ is the capacitance of the sense capacitor, Vₙ is the noise voltage transient at the back plate of the sense capacitor, I_{Ref} is the value of the fixed current source, T₀ is the time at which the periodic reset of the sense capacitor is released, and T₁ is the time at which the voltage sample is taken.

The above equation is useful in facilitating the rejection of noise at a sampling frequency Fₛ and multiples of the sampling frequency, i.e., k·Fₛ. For example, for all noise signals, if the time at which the voltage sample is taken T₁ can coincide with the sampling Fₛ, all noise frequencies which are at multiples of the sampling frequency Fₛ will result in zero aliasing. This is because multiples of the sampling frequency k·Fₛ can be represented as Aₙ sin(k2πFₛ), where Aₙ represents the amplitude of the external (periodic) noise source, and the integral of Aₙ sin(k2πFₛ) over the period from any time at which the periodic reset of the sense capacitor is released (n+1)Tₛ and any time at which the voltage sample is taken nTₛ is equal to zero irrespective of the value of Aₙ.

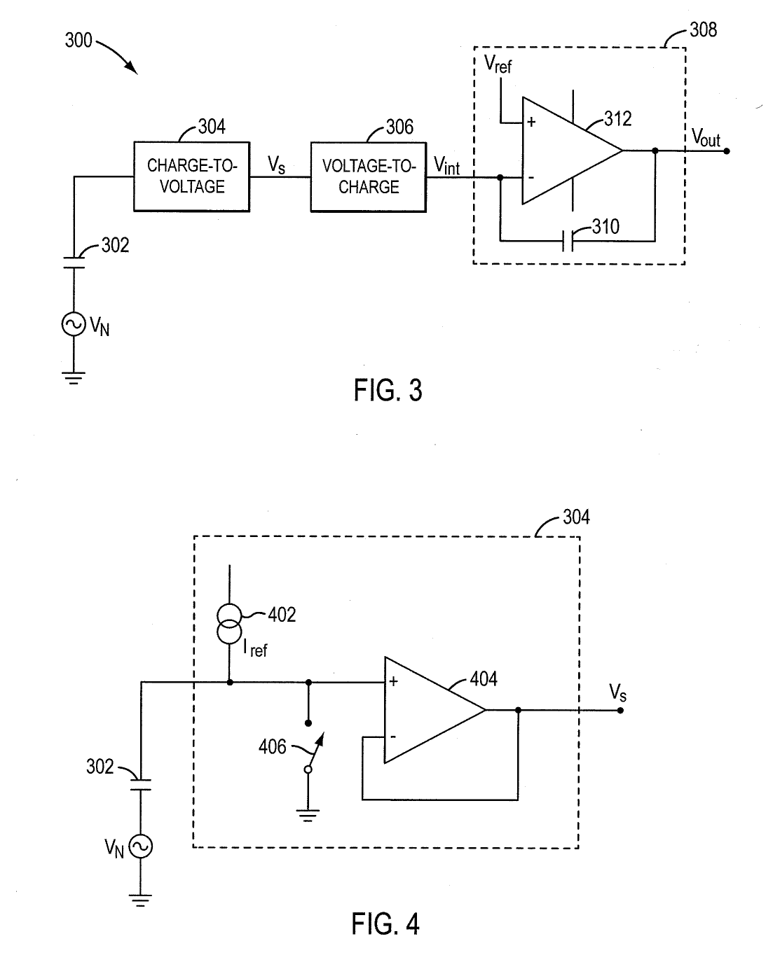

Based on this information, FIG. 3 is a diagram illustrating a capacitive sensor 300 consistent with some embodiments. As shown in FIG. 3, capacitive sensor 300 includes a sense capacitor 302 having a back plate which is coupled to ground. The front plate of sense capacitor 302 is coupled to two circuits which may implement a two stage process for charging and discharging sense capacitor 302 and then sampling a charge from sense capacitor 302. In particular, sense capacitor 302 is first coupled to a charge-to-voltage converter circuit 304. Charge-to-voltage converter circuit 304 includes a current source for charging sense capacitor 302 and generating a time-varying voltage Vₛ. Charge-to-voltage converter circuit 304 also includes circuitry for periodically discharging a voltage build up on sense capacitor 302.

Charge-to-voltage converter circuit 304 is coupled to a voltage-to-charge converter circuit 306 that receives the time-varying voltage Vₛ generated by charge-to-voltage converter circuit 304. Voltage-to-charge converter circuit 306 generates a sampled charge from the time-varying voltage Vₛ that is proportional to the charge on sense capacitor 302 by sampling the time-varying voltage Vₛ and generating a charge proportional to the sampled voltage or a derivative of the sampled voltage depending on the clock phase. The charge generated by voltage-to-charge converter circuit 306 is accumulated in an integrator circuit 308 for providing a measurement of the charge stored on sense capacitor 302. Similar to prior art integrator circuits, integrator circuit 308 includes an integration capacitor 310 coupled to an amplifier 312 in a negative feedback loop, wherein the measurement of the charge stored in integration capacitor 310 is proportional to the charge stored in sense capacitor 302, and can be used to estimate the value of the charge stored in sense capacitor 302.

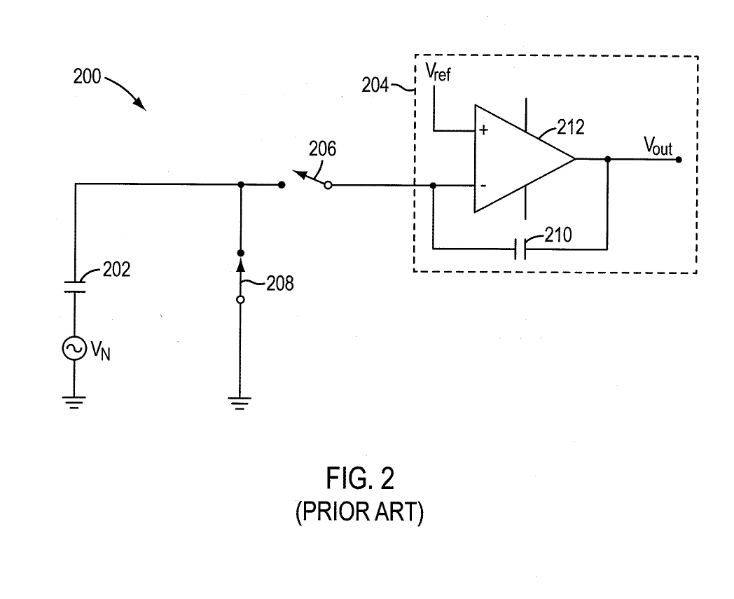

Similar to the prior art device shown in FIG. 2, because capacitor 302 has a back plate that is coupled to ground, noise is introduced, shown as V_{N}. However, unlike the prior art device shown in FIG. 2, instead of using fixed voltage references and switches that periodically connect these references to charge or discharge the sense capacitor of the capacitive sensor, capacitive sensor 300 generates a charge proportional to sense capacitor 302 without incurring aliasing noise from the ground of sense capacitor 302.

FIG. 4 is a diagram illustrating a charge-to-voltage converter circuit 304 consistent with some embodiments. As shown in FIG. 4, charge-to-voltage converter circuit 304 is coupled to sense capacitor 302 and provides circuitry for charging and discharging sense capacitor 302 to generate time-varying voltage Vₛ on sense capacitor 302. Charge-to-voltage converter circuit 304 includes a current source 402 that is coupled to sense capacitor 302 and provides a current I_{Ref} for charging sense capacitor 302. Current source 402 is further coupled to a unity gain buffer 404, which outputs time-varying voltage Vₛ to voltage-to-charge converter circuit 306. Sense capacitor 302 and current source 402 are further coupled to a switch 406 which, when closed, provides a path to ground and allows for the discharge of voltage built up on sense capacitor 302. Switch 406 is periodically closed by the application of a reset pulse Pᵣₛₜ. Depending on the frequency of the reset pulse relative to the sampling frequency, voltage-to-charge converter circuit 306 may have different implementations.

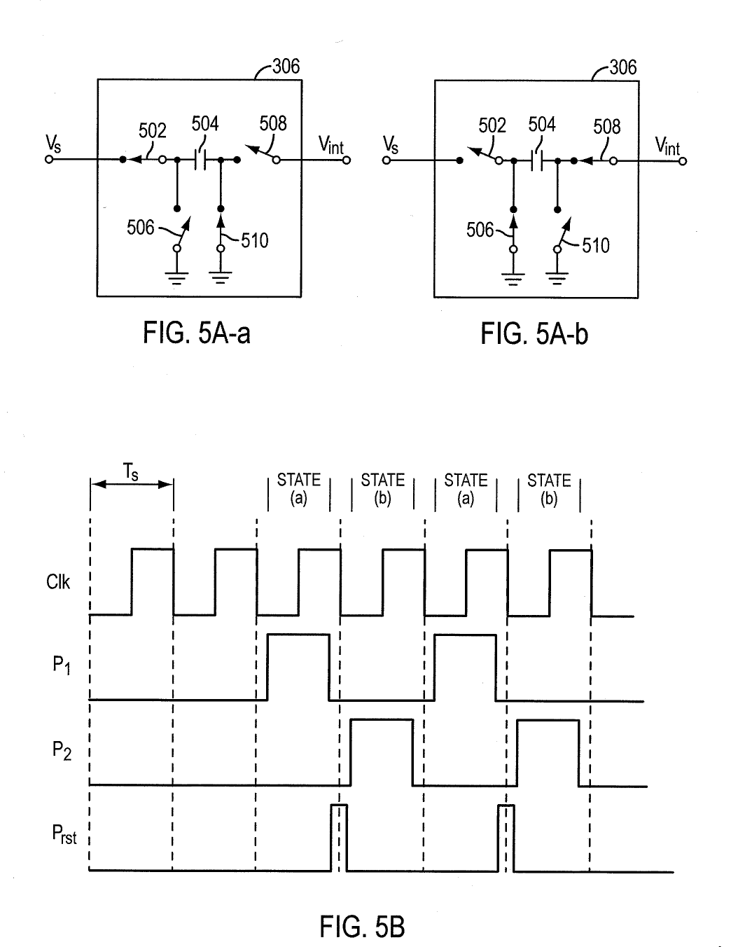

FIG. 5A is a diagram illustrating a voltage-to-charge converter circuit 306 consistent with some embodiments. As shown in FIG. 5A, voltage-to-charge converter circuit 306 includes a first switch 502 coupled between a capacitor 504 and charge-to-voltage converter circuit 304. Voltage-to-charge converter circuit 306 further includes a second switch 506 coupled between first switch 502 and capacitor 504, a third switch 508 coupled between capacitor 504 and integration circuit 308, and a fourth switch 510 coupled between capacitor 504 and third switch 508. Consistent with some embodiments, voltage-to-charge converter circuit 306 as shown in FIG. 5A may be used when the frequency of reset pulse Pᵣₛₜ is the same as sampling frequency Fₛ. Moreover, the magnitude of noise rejections at multiples of the sampling frequency k·Fₛ is inversely proportional to the duration of reset pulse Pᵣₛₜ relative to the sampling period Tₛ.

As shown in FIG. 5A, voltage-to-charge converter circuit is primarily in two states (a) and (b). In state (a), the time-varying voltage is sampled and applied across capacitor 504, accumulating charge on capacitor 504. In state (b), first switch 502 and fourth switch 510 are opened and second switch 506 and third switch 508 are closed, allowing a voltage Vᵢₙₜ generated by the charge accumulated on capacitor 504 to be passed to integration circuit 308. Thus, states (a) and (b) are toggled by the opening and closing of switches 502, 506, 508, and 510. In particular, when switches 502 and 510 are closed and switches 506 and 508 are toggled open, voltage-to-charge converter circuit 306 is in state (a). When switches 502 and 510 are open and switches 506 and 508 are closed, voltage-to-charge converter circuit 306 is in state (b). Consistent with some embodiments, the toggling of switches 502 and 510 is controlled by a first pulse signal P₁, and the toggling of switches 506 and 508 is controlled by a second pulse signal P₂.

FIG. 5B is a timing diagram illustrating the timing of voltage-to-charge converter circuit 306. As shown in FIG. 5B, a clock signal Clk rises and falls during each sample period Tₛ. Periodically, first pulse signal P₁ goes to a high state, which toggles switches 502 and 510 to close. At this time, time-varying voltage Vₛ is being sampled and accumulated on capacitor 504. Consistent with some embodiments, as soon as first pulse signal P₁ returns to a low state, reset pulse Pᵣₛₜ goes to a high state, which toggles switch 406 in charge-to-voltage converter circuit 304, and allows the voltage build up on sense capacitor 302 to be discharged. In response to the falling edge of reset pulse Pᵣₛₜ, second pulse signal P₂ transitions to a high state, toggling switches 506 and 508 to close such that voltage Vᵢₙₜ generated by the charge accumulated on capacitor 504 can be passed to integration circuit 308.

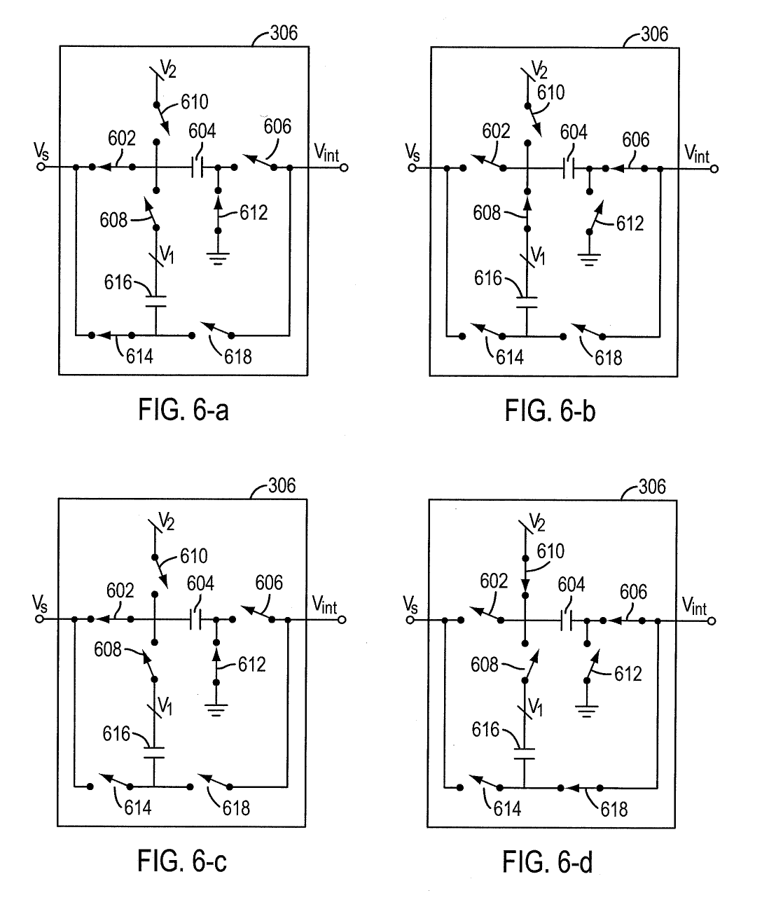

FIG. 6 is a diagram illustrating a voltage-to-charge converter circuit 306 consistent with some embodiments. Voltage-to-charge converter circuit 306 shown in FIG. 6 is similar to voltage-to-charge converter circuit 306 shown in FIG. 5A, and can be utilized, for example, when the period Tᵣₛₜ of the reset pulse Pᵣₛₜ is equal to an integer multiple of the sampling period Tₛ, i.e., when Tᵣₛₜ=n·Tₛ. Moreover, voltage-to-charge converter circuit 306 may provide better noise rejection of noise aliases regardless of the duration of reset pulse Pᵣₛₜ relative to sampling period Tₛ. Furthermore, when the period of the reset pulse Tᵣₛₜ is equal to multiples of the sampling period Tₛ, (n−1) periods of integration include the complete sampling period Tₛ and the last period of integration may be used to partially integrate and partially reset the sense capacitor.

As shown in FIG. 6, voltage-to-charge converter circuit 306 includes a first switch 602 coupled between charge-to-voltage converter circuit 304 and capacitor 604. A second switch 606 is coupled between capacitor 604 and integration circuit 308. A third switch 608 is coupled between a first voltage source V₁ and first capacitor 604, and a fourth switch 610 is coupled between a second voltage source V₂ and capacitor 604. A fifth switch 612 between capacitor 604 and second switch 606. A sixth switch 614 is coupled between charge-to-voltage converter circuit 304 and a second capacitor 616, and a seventh switch 618 is coupled between second capacitor 616 and integration circuit 308.

As shown in FIG. 6, voltage-to-charge circuit may be in one of four states depending on the opening and closing of the switches. State (a) is a first sampling stage, wherein first switch 602, fifth switch 612, and sixth switch 614 are closed, and second 606, third 608, fourth 610, and seventh 618 switches are open. In state (a), time-varying voltage Vₛ is sampled from charge-to-voltage circuit 304 and accumulated on first capacitor 604 and second capacitor 616. In state (b), switches 602, 612, and 614 are opened, while switch 606 is closed, allowing for a voltage Vᵢₙₜ generated by the charge accumulated on capacitor 604 to be passed to integration circuit 308. However, in state (b), switch 608 is also closed, which applies a voltage source dependent on first voltage source V₁ and the time-varying voltage Vₛ accumulated on second capacitor 616 to capacitor 604. This voltage source changes the voltage Vᵢₙₜ generated by the charge accumulated on capacitor 604 by a predetermined amount. In state (c), switches 602 and 612 are closed and switches 606 and 608 are opened. In state (c), time-varying voltage Vₛ is again sampled from charge-to-voltage circuit 304 and accumulated on first capacitor 604. However, from state (b), capacitor 604 also included a charge dependent on both the charge sampled in state (a) and first voltage source V₁. Thus, the charge accumulated on capacitor 604 in state (c) are not only based on the time-varying voltage Vₛ sampled in state (c), but also the time-varying voltage Vₛ sampled in state (a). Then, in state (d), switches 602 and 612 are opened and switches 606, 610 and 616 are closed. Thus, a second voltage source V₂ is applied to first capacitor 604 and the integration voltage Vᵢₙₜ is applied to second capacitor 618. These voltage sources also change the voltage Vᵢₙₜ generated by the charge accumulated on capacitor 604 by a predetermined amount in subsequent sampling phases.

Consistent with some embodiments, the toggling of switches 602, 612, and 614 may be controlled by a first pulse signal P₁. Similarly, switch 608 may be controlled by a second pulse signal P₂, switches 610 and 618 may be controlled by a third pulse signal P₃, and switch 606 may either be controlled by a fourth pulse signal, or it may be controlled by either the second pulse signal P₂ or the third pulse signal P₃ such that switch 606 is toggled closed when either of second pulse signal P₂ and/or third pulse signal P₃ are in a high state.

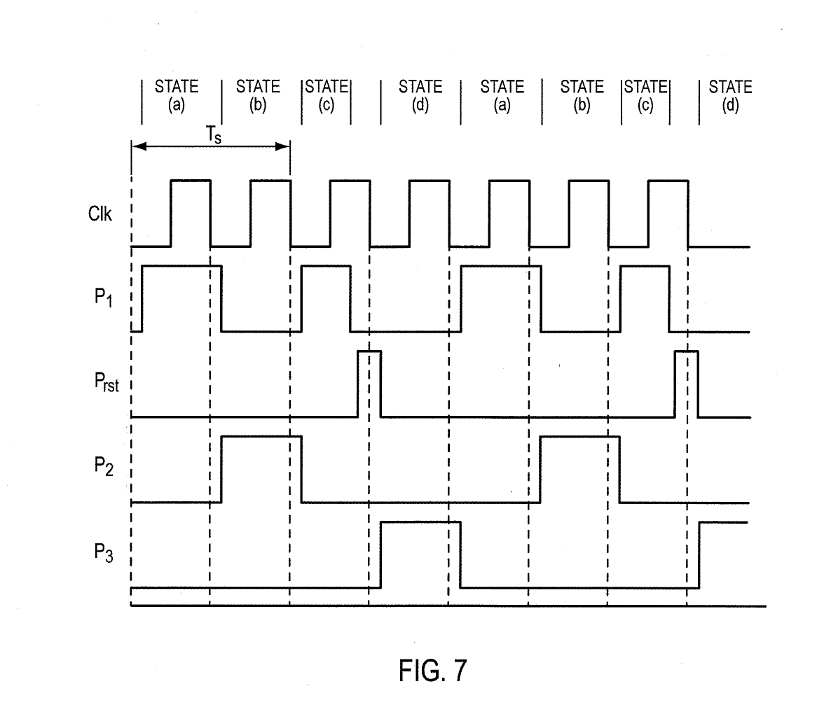

FIG. 7 shows a timing diagram illustrating the timing of voltage-to-charge circuit 306 illustrated in FIG. 6. As shown in FIG. 7, a clock signal Clk transitions from a high state to a low state twice over a single sampling period Tₛ. First pulse signal P₁ periodically transitions from a high state to a low state, toggling first switch 602, fifth switch 612, and sixth switch 614. When first pulse signal P₁ transitions from a high state to a low state, either second pulse signal P₂ transitions to a high state, toggling switch 608 and switch 606 to be closed, or reset pulse Pᵣₛₜ transitions to a high state, which toggles switch 406 in charge-to-voltage converter circuit 304, and allows the voltage build up on sense capacitor 302 to be discharged. When reset pulse Pᵣₛₜ transitions to a low state, third pulse signal P₃ transitions to a high state, toggling switches 610, 606, and 618 to be closed. Consistent with some embodiments, zero noise is sampled during the period of second pulse signal P₂ because the integration period coincides with the noise period. Any noise sampled during the period of third pulse signal P₃ will only occur at ½·Fₛ. Thus, this noise can be easily removed using a digital signal processor specifically programmed to reduce the noise at ½·Fₛ. Any noise aliasing caused by the beat frequencies of the reset pulse frequency Fᵣₛₜ and sampling frequency Fₛ can be handled through discrete-time processing of charge samples. Consistent with the embodiments shown in FIGS. 6 and 7, a discrete-time differentiator can be used to reject the noise aliasing caused by beat frequencies Fᵣₛₜ and Fₛ as the sampled voltage in states (c) and (d) are dependent, in part, on the sampled voltage in state (a).

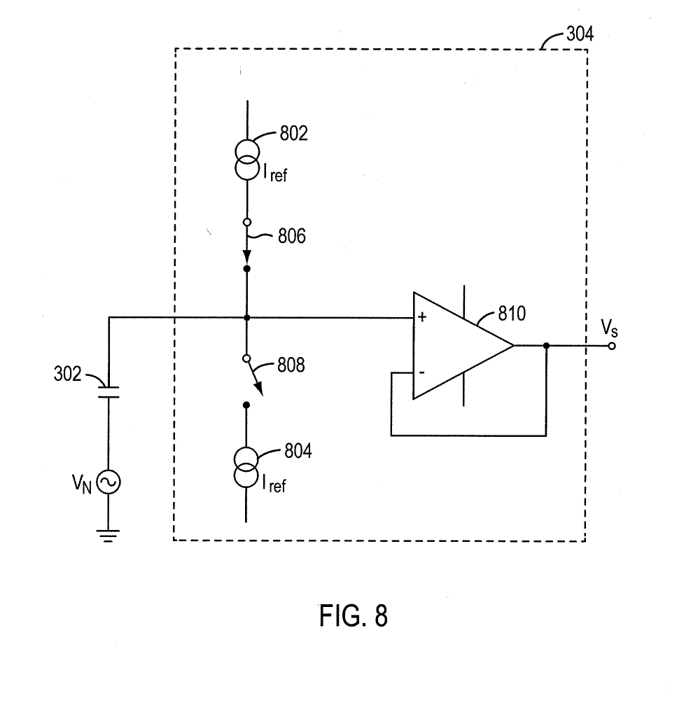

FIG. 8 is a diagram illustrating a charge-to-voltage converter circuit 304 consistent with some embodiments. As shown in FIG. 8, charge-to-voltage converter circuit 304 is coupled to sense capacitor 302 and provides circuitry for charging and discharging sense capacitor 302 to generate time-varying voltage Vₛ on sense capacitor 302. Charge-to-voltage converter circuit 304 includes a first current source 802 that is coupled to sense capacitor 302 and provides a current I_{Ref} for charging sense capacitor 302. Charge-to-voltage converter circuit 304 also includes a second current source 804 that is coupled to sense capacitor 302 and provides a current −I_{Ref} to sense capacitor 302 for discharging sense capacitor 302. Charge-to-voltage converter circuit 304 as shown in FIG. 8 may require using at lease two full sample periods 2·Tₛ for charging sense capacitor 302 and the following two full sample periods to discharge sense capacitor 302.

Referring to FIG. 8, current sources 802 and 804 are respectively coupled to sense capacitor 302 via switches 806 and 808. Consistent with some embodiments, switch 806 is toggled via a first charge pulse signal P_{ch1} and switch 808 is toggled via a second charge pulse signal P_{ch2} which transitions to a high state when first charge pulse signal P_{ch1} transitions to a low state. Current sources 802 and 804 are further coupled to a unity gain buffer 810, which outputs time-varying voltage Vₛ to voltage-to-charge converter circuit 306.

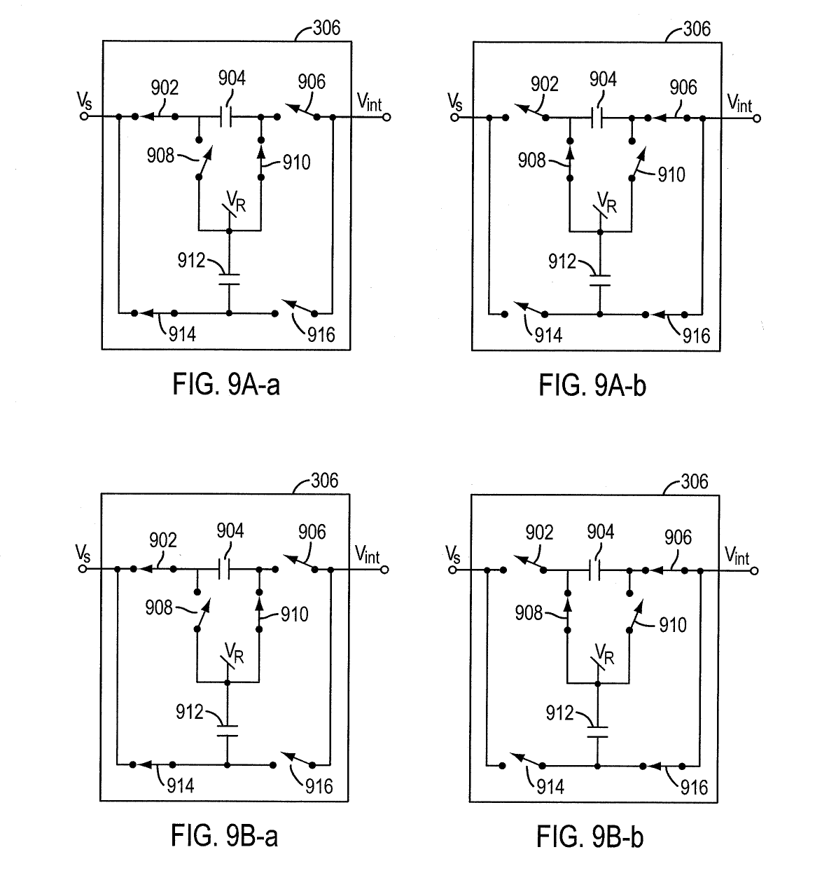

FIGS. 9A and 9B are diagrams illustrating the processing stages of a voltage-to-charge converter circuit 306 consistent with some embodiments. In particular, FIG. 9A illustrates a first processing stage that is used to remove aliases at integer multiples of the sampling frequency Fₛ, and FIG. 9B illustrates a second processing stage that is used to remove aliases of noises at half the sampling frequency 0.5 F_{S}. Consistent with the embodiments shown in FIGS. 9A and 9B, voltage-to-charge converter circuit 306 generates a sampled charge to be integrated which is proportional to an absolute value of the sampled voltage with respect to a reference voltage V_{R}, and the separate processing stages shown in FIGS. 9A and 9B operate in parallel.

As shown in FIG. 9A voltage-to-charge converter circuit 306 includes a first switch 902 coupled between charge-to-voltage converter circuit 304 and first capacitor 904. A second switch 906 is coupled between capacitor 904 and integration circuit 308. A third switch 908 is coupled between a reference voltage source V_{R} and first switch 902, and a fourth switch 910 is coupled between reference voltage source V_{R} and second switch 906. Voltage-to-charge converter circuit 306 also includes a second capacitor 912 coupled between reference voltage source and a fifth switch 914 and a sixth switch 916.

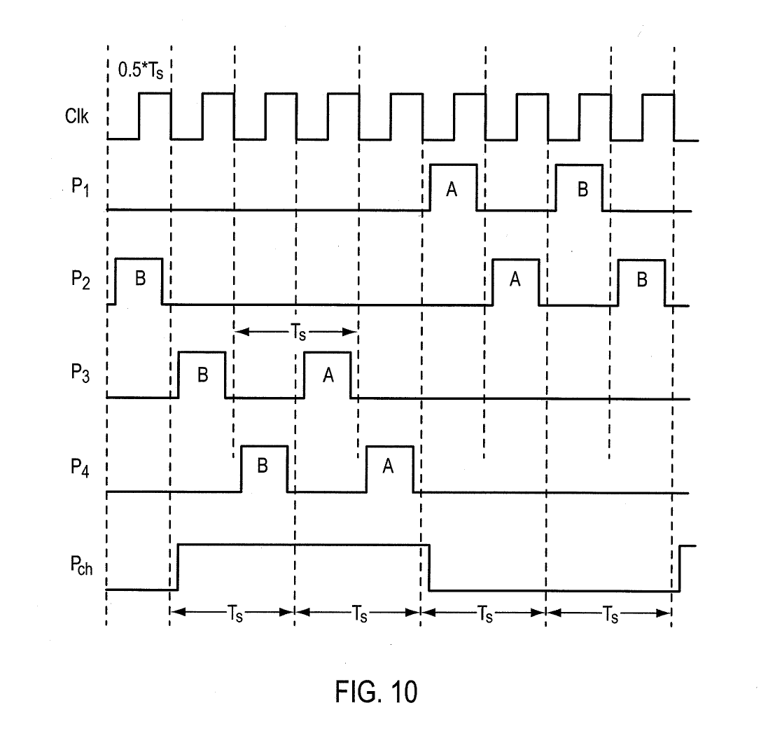

As shown in FIG. 9A, voltage-to-charge circuit 306 may be in one of two states depending on the opening and closing of the switches. State (a) is a sampling state, wherein first switch 902, fourth switch 910 and fifth switch 914 are closed, and second 906, third 908, and sixth 916 switches are open. In state (a), time-varying voltage Vₛ is sampled from charge-to-voltage circuit 304 and accumulated on first capacitor 904 and second capacitor 912. State (b) is an integration state, wherein switches 902, 910, and 914 are opened and switches 906, 906, and 916 are closed, such that a voltage Vᵢₙₜ generated by the charge accumulated on first capacitor 904 can be passed to integration circuit 308. In state (b), a charge dependent on both reference voltage V_{R} and time-varying voltage Vₛ sampled in state (a) is accumulated on first capacitor 904. Consistent with some embodiments, the toggling of switches 902, 910 and 914 may be controlled by a first pulse signal P₁ and a third pulse signal P₃, and switches 906, 908, and 916 may be controlled by a second pulse signal P₂ and a fourth pulse signal P₄ as discussed below with respect to FIG. 10. Voltage-to-charge converter circuit 306 as shown in FIG. 9A distinguishes the signal component and aliases of noise at multiples of the sampling frequency Fₛ by converting the signal component to a direct current (DC) charge, and converting the aliases of noise to a sinusoidal charge which is removed during the integration state.

FIG. 9B illustrates a second processing stage that is used to remove aliases of noises at half the sampling frequency 0.5 F_{S}. As shown in FIG. 9B, the second processing stage of voltage-to-charge converter circuit 306 includes a first switch 902 coupled between charge-to-voltage converter circuit 304 and first capacitor 904. A second switch 906 is coupled between capacitor 904 and integration circuit 308. A third switch 908 is coupled between a reference voltage source V_{R} and first switch 902, and a fourth switch 910 is coupled between reference voltage source V_{R} and second switch 906. Voltage-to-charge converter circuit 306 also includes a second capacitor 912 coupled between reference voltage source V_{R} and a fifth switch 914 and a sixth switch 916.

As shown in FIG. 9B, voltage-to-charge circuit 306 may be in one of two states depending on the opening and closing of the switches. State (a) is a sampling state, wherein first switch 902, fourth switch 910 and fifth switch 914 are closed, and second 906, third 908, and sixth 916 switches are open. In state (a), time-varying voltage Vₛ is sampled from charge-to-voltage circuit 304 and accumulated on first capacitor 904 and second capacitor 912. State (b) is an integration state, wherein switches 902, 910, and 914 are opened and switches 906, 906, and 916 are closed, such that a voltage Vᵢₙₜ generated by the charge accumulated on first capacitor 904 can be passed to integration circuit 308. In state (b), a charge dependent on both reference voltage V_{R} and time-varying voltage Vₛ sampled in state (a) is accumulated on first capacitor 904. Similar to FIG. 9A, the toggling of switches 902, 910, and 914 may be controlled by first pulse signal P₁ and third pulse signal P₃, and switches 906, 908, and 916 may be controlled by second pulse signal P₂ and fourth pulse signal P₄ as discussed below with respect to FIG. 10. The second processing stage of voltage-to-converter circuit 306 as shown in FIG. 9 prevents aliases of noise at half of the sampling frequency Fₛ by subtracting the charges of successive samples in phases A and B, using a differentiator, and then converting the noise to a frequency which can be distinguished from the signal. The noise can then be subtracted from the signal, thus preventing noise at half of the sampling frequency. Similar to the embodiments shown in FIGS. 7 and 8, any noise aliasing caused by the beat frequencies of the charge pulse frequency F_{ch} and sampling frequency Fₛ can be handled through discrete-time processing of charge samples.

FIG. 10 shows a timing diagram illustrating the timing of both processing stages of voltage-to-charge circuit 306 illustrated in FIGS. 9A and 9B. As shown in FIG. 10, a clock signal Clk transitions from a high state to a low state twice over a single sampling period Tₛ and the period of a charge pulse signal P_{ch} being equal to nTₛ (with n=2 in an embodiment shown in FIG. 10). First pulse signal P₁, second pulse signal P₂, third pulse signal P₃, and fourth pulse signal P₄ each have a first phase A and a second phase B, phase A representing a time when a voltage at first capacitor 904 is greater than reference voltage V_{R} and phase B representing a time when a voltage at first capacitor 904 is less than reference voltage V_{R}. In addition, first pulse signal P₁ and second pulse signal P₂ represents a time when a derivative of the voltage at first capacitor 904 is negative, and third pulse signal P₃ and fourth pulse signal P₄ represent a time when a derivative of the voltage at first capacitor 904 is positive.

Consistent with the first processing stage shown in FIG. 9A, phase A of first pulse signal P₁ and third pulse signal P₃ toggles fifth switch 914, and phase B of first pulse signal P₁ and third pulse signal P₃ toggles first switch 902 and fourth switch 910. Phase A of second pulse signal P₂ and fourth pulse signal P₄ toggles sixth switch 916, and phase B of second pulse signal P₂ and fourth pulse signal P₄ toggles second switch 906 and third switch 908.

With respect to the second processing stage shown in FIG. 9B, both phases A and B of third pulse signal P₃ toggles first switch 902 and fourth switch 910. Both phase A of second pulse signal P₂ and phase B of fourth pulse signal P₄ toggles second switch 906, third switch 908, and sixth switch 916. Both phase A and phase B of first pulse signal P₁ toggles fifth switch 914.

As shown in FIGS. 8, 9A, 9B, and 10, two full sample periods 2Tₛ are used for charging sense capacitor 302, and the following two full sample periods are used to discharge sense capacitor 302. This results in a proportional charge to be integrated which is proportional to an absolute value of the sampled voltage with respect to reference voltage V_{R}. Since the integration period with respect to noise is the same as the sample period Tₛ, but the current source switches polarity once during the integration cycle, a noise charge having equal but opposite polarity is injected into the system every other cycle. The first processing stage of voltage-to-charge converter circuit 306 as shown in FIG. 9A distinguishes the signal component and aliases of noise at multiples of the sampling frequency Fₛ by converting the signal component to a direct current (DC) charge, and converting the aliases of noise to a sinusoidal charge which is removed during the integration state. The second processing stage of voltage-to-converter circuit 306 as shown in FIG. 9 prevents aliases of noise at half of the sampling frequency Fₛ by subtracting the charges of successive samples in phases A and B, using a differentiator, and then converting the noise to a frequency which can be distinguished from the signal. The noise can then be subtracted from the signal, thus preventing noise at half of the sampling frequency.

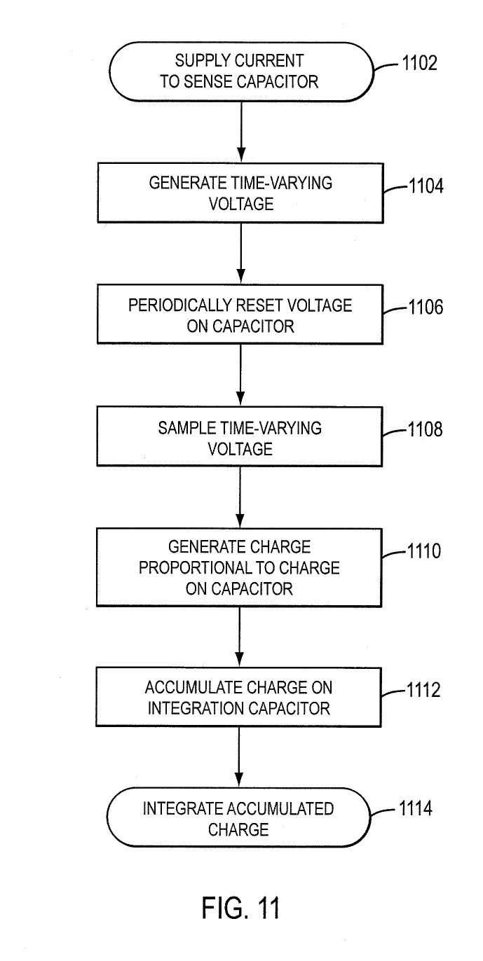

FIG. 11 is a flowchart illustrating a method for generating a signal proportional to a charge of a capacitor having reduced noise consistent with some embodiments. The method illustrated in FIG. 11 may be performed by any of the embodiments herein, and will be discussed in accordance with some of the embodiments disclosed herein. First, a reference current I_{Ref} is supplied to sense capacitor 302 by a current source in charge-to-voltage converter circuit 304 (step 1102). The reference current I_{Ref} generates a time-varying voltage Vₛ on sense capacitor 302 (step 1104). Over time, the time-varying voltage Vₛ builds up on sense capacitor 302 and, thus, the time-varying voltage Vₛ is periodically reset by charge-to-voltage converter circuit 304 (step 1106). According to some embodiments, the time-varying voltage Vₛ build up on sense capacitor 302 may be reset by toggling switch 406 which provides a path to ground with a reset pulse Pᵣₛₜ, as shown in FIG. 4. In other embodiments, the time-varying voltage Vₛ build up on sense capacitor 302 may be reset by applying a second current source having an equal magnitude but opposite polarity −I_{Ref} to sense capacitor 302, as shown in FIG. 8.

The time-varying voltage Vₛ generated by supplying the reference current I_{Ref} to sense capacitor 302 is sampled by voltage-to-charge converter circuit 306 (step 1108). The time-varying voltage Vₛ is accumulated on a capacitor such as capacitor 504, 604 or 904, thereby generating a charge proportional to the charge on sense capacitor 302 (step 1110). The generated charge produces an integration voltage Vᵢₙₜ that is accumulated an integrator circuit 308, where the integration voltage Vᵢₙₜ is applied across an integration capacitor 310 and generates a charge that is proportional to the charge on sense capacitor 302 (step 1112). The charge accumulated on integration capacitor is integrated over time, and then measured to provide a reading of the charge stored on sense capacitor 302 (step 1114).

Embodiments as described herein may provide a two-stage circuit for reducing noise in a capacitive sensing device, and a method thereof. Consistent with some embodiments, the circuit and method described herein may provide greater elimination of aliasing noise by avoiding aliasing altogether. The examples provided above are exemplary only and are not intended to be limiting. One skilled in the art may readily devise other systems consistent with the disclosed embodiments which are intended to be within the scope of this disclosure. As such, the application is limited only by the following claims.

What is claimed is:

1. A capacitive sensing circuit, comprising:
a first capacitor;
a charge-to-voltage converter circuit coupled to the first capacitor, the charge-to-voltage converter circuit including a first current source that provides a first current to the first capacitor to charge the first capacitor and generate a time-varying voltage;
a voltage-to-charge converter circuit coupled to the charge-to-voltage converter circuit, the voltage-to-charge converter circuit sampling the time-varying voltage and converting the time-varying voltage into a sampled charge at a predetermined sampling frequency; and
an integrator circuit coupled to the voltage-to-charge circuit, the integrator circuit receiving the sampled charge and integrating the sampled charge.

2. The circuit according to claim 1, wherein a voltage build up on the first capacitor is periodically reset to zero.

3. The circuit according to claim 2, wherein the voltage build up is periodically reset to zero by providing a path to ground toggled by a reset pulse having a predetermined frequency.

4. The circuit according to claim 3, wherein the voltage-to-charge converter circuit comprises:
a first switch coupled to the charge-to-voltage converter circuit;
a second capacitor coupled to the first switch;
a second switch coupled between the second capacitor and ground;
a third switch coupled between the second capacitor and ground; and
a fourth switch coupled between the second capacitor and the integrator circuit, wherein:
the first and third switch open and the second and fourth switch close on the falling edge of the reset pulse.

5. The circuit according to claim 4, wherein the predetermined frequency is equal to the sampling frequency.

6. The circuit according to claim 3, wherein the voltage-to-charge converter circuit comprises:
a first switch coupled to the charge-to-voltage circuit;
a second capacitor coupled to the first switch;
a second switch coupled between the second capacitor and the integrator circuit;
a third switch coupled between the second capacitor and a first voltage source;
a fourth switch coupled between the second capacitor and a second voltage source;
a fifth switch coupled between the second capacitor and ground;
a sixth switch coupled between the charge-to-voltage converter circuit and a third capacitor; and
a seventh switch coupled between the third capacitor and the integrator circuit, wherein:
the sampled charge is transmitted to the integrator circuit a single sampling period following a falling edge of the reset pulse.

7. The circuit according to claim 6, wherein the predetermined frequency is an integer multiple of a sampling period of the sampled charge.

8. The circuit according to claim 2, wherein the voltage build up is periodically reset to zero using a second current source, the second current source providing a second current having a magnitude that is equal to a magnitude of the first current but having a polarity that is opposite to a polarity of the first current.

9. The circuit according to claim 8, wherein the charge-to-voltage converter circuit comprises:
a charge switch and a discharge switch coupled between the first capacitor and a buffer, wherein
the charge switch, when closed, couples the first current source to the first capacitor to charge the first capacitor; and
the discharge switch, when closed, couples the second current source to the first capacitor to discharge the sense capacitor.

10. The circuit according to claim 9, wherein the first capacitor is charged over a full sample period, and the first capacitor is discharged over the subsequent full sample period.

11. The circuit according to claim 8, wherein the voltage-to-charge circuit is configured to generate the sampled charge to be proportional to an absolute value of the time-varying voltage with respect to a reference voltage source.

12. The circuit according to claim 8, wherein the voltage-to-charge circuit comprises:
a first switch coupled between the charge-to-voltage circuit and a second capacitor;
a second switch coupled between the second capacitor and the integrator circuit;
a third switch coupled between a reference voltage source and the second capacitor;
a fourth switch coupled the reference voltage source and the second capacitor;
a fifth switch coupled between the charge-to-voltage circuit and a third capacitor; and
a sixth switch coupled between the third capacitor and the integrator circuit.

13. The circuit according to claim 12, wherein the voltage-to-charge converter circuit samples the time-varying voltage in a sampling stage and sends the sampled charge to the integrator circuit in an integration stage, and further wherein:
during the first sampling stage, the first switch, the fourth switch, and the fifth switch are closed, while the second, third, and sixth switches are open, coupling the time-varying voltage to the second capacitor; and
during the integration stage, the second, third, and sixth switches are closed, while the first, fourth, and fifth switches are open, coupling the second capacitor storing the sampled charge to the integrator circuit.

14. The circuit of claim 12, wherein the voltage-to-charge converter circuit includes at least two processing stages which operate in parallel, the first processing stage removes noise at integer multiples of a sampling frequency of sampling the charge, and the second processing stage removes noise at half of the frequency of the sampling frequency.

15. A method of generating a signal proportional to a charge of a capacitor, the generated signal having reduced noise, comprising:
generating a time-varying voltage across a first capacitor by supplying a first current produced by a first current source to the capacitor, wherein a voltage build up on the first capacitor is periodically reset;
sampling the time-varying voltage;
generating a proportional charge that is proportional to a charge stored on the first capacitor based on the sampled time-varying voltage; and
accumulating the proportional charge on a second capacitor.

16. The method of claim 15, wherein periodically resetting the voltage build up on the first capacitor comprises generating a reset pulse at a first predetermined frequency, the reset pulse toggling a switch that provides a path to ground.

17. The method of claim 16, wherein generating a proportional charge comprises:
sampling the time-varying voltage across a third capacitor at a second predetermined frequency; and
providing a path from the third capacitor to the second capacitor in response to a falling edge of the reset pulse.

18. The method of claim 15, wherein periodically resetting the voltage build up on the first capacitor comprises:
periodically stopping the supply of the first current to the first capacitor;
and supplying a second current from a second current source to the first capacitor, the second current having a magnitude that is equal to a magnitude of the first current but having a polarity that is opposite to a polarity of the first current.

19. The method of claim 18, wherein generating the proportional charge comprises:
sampling the time-varying voltage across a third capacitor;
periodically coupling the third capacitor to a reference voltage source; and
after coupling the third capacitor to the reference voltage source, periodically coupling the third capacitor to the second capacitor.

20. The method of claim 19, wherein the proportional charge is proportional to the time-varying voltage and the reference voltage.
